(19) United States
(12) Patent Application Publication
(10) Pub. No.: US 2026/0203889 A1
(43) Pub. Date: Jul. 16, 2026

(54) IMAGE PROCESSING APPARATUS AND IMAGE PROCESSING METHOD

(71) Applicant: Lasertec Corporation, Yokohama (JP)

(72) Inventors: Hiroki MIYAI, Yokohama-shi (JP); Toru ADACHI, Yokohama-shi (JP)

(21) Appl. No.: 19/449,221

(22) Filed: Jan. 14, 2026

(30) Foreign Application Priority Data
Jan. 16, 2025 (JP) 2025-006110

(51) Int. Cl. G06T 7/00; G01N 21/956; G03F 1/84

(52) U.S. Cl. CPC G06T 7/0008; G01N 21/95607; G03F 1/84; G06T 7/001; G01N 2021/95676; G06T 2207/20081; G06T 2207/30148

(57) ABSTRACT

An image processing apparatus and an image processing method capable of evaluating a defect candidate found on a pattern surface in consideration of an influence when the pattern surface is transferred to a wafer with a simple configuration are provided. An image processing apparatus according to this embodiment includes: a first acquisition unit configured to acquire an evaluation image which is based on a result of imaging a pattern surface on which a pattern of an evaluation target mask is formed, a second acquisition unit configured to acquire a conversion parameter which is based on a relation between a captured image of the pattern surface and a transfer image when the pattern surface is transferred to a wafer in an exposure apparatus, and a third acquisition unit configured to acquire a converted evaluation image by applying the conversion parameter to the evaluation image.

### INCORPORATION BY REFERENCE

This application is based upon and claims the benefit of priority from Japanese patent application No. 2025-006110, filed on Jan. 16, 2025, the disclosure of which is incorporated herein in its entirety by reference for all purposes.

### BACKGROUND

The present disclosure relates to an image processing apparatus and an image processing method.

Patent Literature 1 and 2 disclose techniques for inspecting a defect of a mask on which a pattern is formed.
[Patent Literature 1] Japanese Patent No. 6249513
[Patent Literature 2] Japanese Unexamined Patent Application Publication No. 2008-032827
[Non-Patent Literature 1] Masaki Hayashi, “CVML expert guide”, [online], [searched on Jan. 7, 2025], Internet <URL: https://cvml-expertguide.net/2021/07/12/spatial-filtering/>

### SUMMARY

Incidentally, it may be preferable to determine whether a defect candidate found on a pattern surface on which a pattern is formed should be detected as abnormal in consideration of an influence when the pattern surface is transferred to a wafer. Patent Literature 2 discloses that a pattern including a defect is inspected and corrected in an apparatus having optical characteristics the same as those of an exposure apparatus.

It is difficult, however, to separately create an inspection apparatus in accordance with optical conditions of the exposure apparatus.

The present disclosure has been made in view of the aforementioned problem, and provides an image processing apparatus and an image processing method capable of evaluating a defect candidate found on a pattern surface in consideration of an influence when the pattern surface is transferred to a wafer with a simple configuration.

An image processing apparatus according to one aspect of this embodiment includes: a first acquisition unit configured to acquire an evaluation image which is based on a result of imaging a pattern surface on which a pattern of an evaluation target mask is formed; a second acquisition unit configured to acquire a conversion parameter which is based on a relation between a captured image of the pattern surface and a transfer image when the pattern surface is transferred to a wafer in an exposure apparatus; and a third acquisition unit configured to acquire a converted evaluation image by applying the conversion parameter to the evaluation image.

In the above image processing apparatus, the second acquisition unit may acquire a lithography condition including an optical condition and a resist condition of the exposure apparatus and determine the conversion parameter based on the lithography condition.

In the above image processing apparatus, the second acquisition unit may train and determine the conversion parameter by machine learning which uses the captured image and the transfer image as a training data set.

In the above image processing apparatus, the second acquisition unit may determine, as the conversion parameter, a kernel which makes the captured image coincide with the transfer image when the kernel is applied to the captured image.

In the above image processing apparatus, the evaluation image may acquire the captured image, and the third acquisition unit may acquire, as the converted evaluation image, a converted captured image obtained by performing convolution integration in which the captured image is multiplied by the kernel.

In the above image processing apparatus, the second acquisition unit may determine the conversion parameter based on a function in an optical model that acquires information of the pattern surface from the captured image and a function in an optical model that acquires the transfer image from the information of the pattern surface.

In the above image processing apparatus, the first acquisition unit may acquire a difference image indicating a difference between the captured image and a reference image corresponding to the captured image as the evaluation image, and the third acquisition unit may acquire a converted difference image obtained by applying the conversion parameter to the difference image as the converted evaluation image.

The above image processing apparatus may further include a determination unit configured to determine whether the difference image satisfies a predetermined condition, in which when the determination unit determines that the predetermined condition is satisfied, the third acquisition unit may acquire the converted difference image as the converted evaluation image.

The above image processing apparatus may include an evaluation unit configured to determine that there is a defect in the evaluation target mask when a predetermined defective image is detected in the converted difference image.

The above image processing apparatus may further include a determination unit configured to determine classification of a defective image shown in the difference image, in which the second acquisition unit may acquire, in accordance with the classification determined by the determination unit, a correction conversion parameter obtained by correcting the conversion parameter as the conversion parameter, and the third acquisition unit may acquire, as the converted evaluation image, a difference image after correction conversion obtained by applying the correction conversion parameter to the difference image.

The above image processing apparatus may further include a determination unit configured to determine a defective image shown in the converted difference image as a defect in a specific classification.

In the above image processing apparatus, the second acquisition unit may acquire another parameter different from the conversion parameter as a conversion parameter, the third acquisition unit may acquire a difference image after other conversion obtained by applying the other parameter to the difference image, and the determination unit may determine a defective image shown in the converted difference image as a defect of first classification and determine a defective image shown in the difference image after other conversion as a defect of second classification.

The above image processing apparatus may further include a determination unit configured to determine whether the evaluation target mask satisfies a predetermined condition, in which when the determination unit determines that the predetermined condition is satisfied, the third acquisition unit may acquire the converted evaluation image.

In the above image processing apparatus, the predetermined condition may include at least one of a condition that the pattern surface of the evaluation target mask is illuminated in a specific illumination distribution in the exposure apparatus and a condition that the pattern surface has a specific shape.

An image processing method according to one aspect of this embodiment includes: a step of acquiring an evaluation image which is based on a result of imaging a pattern surface on which a pattern of an evaluation target mask is formed; a step of acquiring a conversion parameter which is based on a relation between a captured image of the pattern surface and a transfer image when the pattern surface is transferred to a wafer in an exposure apparatus; and a step of acquiring a converted evaluation image by applying the conversion parameter to the evaluation image.

In the above image processing method, in the step of acquiring the conversion parameter, a lithography condition including an optical condition and a resist condition of the exposure apparatus may be acquired and the conversion parameter may be determined based on the lithography condition.

In the above image processing method, in the step of acquiring the conversion parameter, the conversion parameter may be trained and determined by machine learning which uses the captured image and the transfer image as a training data set.

In the above image processing method, in the step of acquiring the conversion parameter, a kernel which makes the captured image coincide with the transfer image when the kernel is applied to the captured image may be determined as the conversion parameter.

In the above image processing method, the evaluation image may include the captured image, and in the step of acquiring the converted evaluation image, a converted captured image obtained by performing convolution integration in which the captured image is multiplied by the kernel may be acquired as the converted evaluation image.

In the above image processing method, in the step of acquiring the conversion parameter, the conversion parameter may be determined based on a function in an optical model that acquires information of the pattern surface from the captured image and a function in an optical model that acquires the transfer image from the information of the pattern surface.

In the above image processing method, in the step of acquiring the evaluation image, a difference image indicating a difference between the captured image and a reference image corresponding to the captured image may be acquired as the evaluation image, and in the step of acquiring the converted evaluation image, a converted difference image obtained by applying the conversion parameter to the difference image may be acquired as the converted evaluation image.

The above image processing method may further include a step of determining whether the difference image satisfies a predetermined condition, in which when it is determined, in the step of determining, that the predetermined condition is satisfied, in the step of acquiring the converted evaluation image, the converted difference image may be acquired as the converted evaluation image.

The above image processing method may include a step of determining that there is a defect in the evaluation target mask when a predetermined defective image is detected in the converted difference image.

The above image processing method may further include a step of determining classification of a defective image shown in the difference image, in which in the step of acquiring the conversion parameter, a correction conversion parameter obtained by correcting the conversion parameter may be acquired as the conversion parameter in accordance with the determined classification, and in the step of acquiring the converted evaluation image, a difference image after correction conversion obtained by applying the correction conversion parameter to the difference image may be acquired as the converted evaluation image.

The above image processing method may further include a step of determining a defective image shown in the converted difference image as a defect in a specific classification.

In the above image processing method, in the step of acquiring the conversion parameter, another parameter different from the conversion parameter may be acquired as the conversion parameter, in the step of acquiring the converted evaluation image, a difference image after other conversion obtained by applying the other parameter to the difference image may be acquired, and in the step of determining, a defective image shown in the converted difference image may be determined as a defect of first classification and a defective image shown in the difference image after other conversion may be determined as a defect of second classification.

The above image processing method may further include a step of determining whether the evaluation target mask satisfies a predetermined condition, in which when it is determined, in the step of determining, that the predetermined condition is satisfied, in the step of acquiring the converted evaluation image, the converted evaluation image may be acquired.

In the above image processing method, the predetermined condition may include at least one of a condition that the pattern surface of the evaluation target mask is illuminated in a specific illumination distribution in the exposure apparatus and a condition that the pattern surface has a specific shape.

According to the present disclosure, it is possible to provide an image processing apparatus and an image processing method capable of evaluating a defect candidate found on a pattern surface in consideration of an influence when the pattern surface is transferred to a wafer with a simple configuration.

The above and other objects, features and advantages of the present disclosure will become more fully understood from the detailed description given hereinbelow and the accompanying drawings.

### BRIEF DESCRIPTION OF DRAWINGS

FIG. 1 is a block diagram illustrating an image processing apparatus according to a first embodiment;

FIG. 2 is a diagram illustrating an evaluation image that a first acquisition unit has acquired in the image processing apparatus according to the first embodiment;

FIG. 3 is a diagram illustrating an evaluation image that the first acquisition unit has acquired in the image processing apparatus according to the first embodiment, and shows a captured image as an evaluation image;

FIG. 4 is a diagram illustrating the evaluation image that the first acquisition unit has acquired in the image processing apparatus according to the first embodiment, and shows a difference image as an evaluation image;

FIG. 5 is a diagram illustrating a reference image D1 that the first acquisition unit uses to acquire the difference image in the image processing apparatus according to the first embodiment;

FIG. 6 is a diagram illustrating a captured image that a second acquisition unit uses to acquire conversion parameters in the image processing apparatus according to the first embodiment;

FIG. 7 is a diagram illustrating a wafer image that the second acquisition unit uses to acquire conversion parameters in the image processing apparatus according to the first embodiment;

FIG. 8 is a schematic view illustrating a kernel that the second acquisition unit acquires as a conversion parameter in the image processing apparatus according to the first embodiment;

FIG. 9A is a diagram illustrating an optical model that the second acquisition unit uses to acquire conversion parameters in the image processing apparatus according to the first embodiment, and shows an optical model of an optical apparatus for acquiring a captured image of a pattern surface of an evaluation target mask;

FIG. 9B is a diagram illustrating an optical model that the second acquisition unit uses to acquire conversion parameters in the image processing apparatus according to the first embodiment, and shows an optical model of an exposure apparatus that performs a lithography process using an evaluation target mask as a patterning device;

FIG. 10 is a diagram illustrating a converted evaluation image acquired by a third acquisition unit in the image processing apparatus according to the first embodiment;

FIG. 11 is a flowchart illustrating an image processing method according to the first embodiment;

FIG. 12 is a block diagram illustrating an image processing apparatus according to a second embodiment;

FIG. 13 is a diagram illustrating conversion parameters that the second acquisition unit acquires and a converted evaluation image that the third acquisition unit acquires in the image processing apparatus according to the second embodiment;

FIG. 14 is a diagram illustrating conversion parameters that the second acquisition unit acquires and a converted evaluation image that the third acquisition unit acquires in the image processing apparatus according to the second embodiment;

FIG. 15 is a diagram illustrating conversion parameters that the second acquisition unit acquires and a converted evaluation image that the third acquisition unit acquires in the image processing apparatus according to the second embodiment;

FIG. 16 is a flowchart illustrating an image processing method according to the second embodiment; and

FIG. 17 is a configuration diagram illustrating an inspection apparatus as an optical apparatus according to a third embodiment.

### DESCRIPTION OF EMBODIMENTS

Embodiments according to the present disclosure will be described hereinafter with reference to the drawings. In the following description, embodiments according to the present disclosure are shown, and the scope of the present disclosure is not limited to the below-shown embodiments. In the following description, components/structures to which the same reference numerals (or symbols) are assigned are substantially the same as each other.

### First Embodiment

An image processing apparatus and an image processing method according to a first embodiment will be described. The image processing apparatus according to this embodiment may be an evaluation apparatus that evaluates an evaluation target. The evaluation target includes, for example, a photomask. The photomask of the evaluation target is referred to as an evaluation target mask. The photomask may be the one on which a pattern is formed. The evaluation apparatus may include, as the evaluation target, not only a photomask but also a semiconductor substrate, a semiconductor chip, and a semiconductor device. The image processing apparatus may be a part of an optical apparatus such as an inspection apparatus. Further, the image processing apparatus may be a part of an apparatus (review apparatus) configured to display an obtained image (e.g., captured image) on a display or the like as a result of illumination of the evaluation target. Further, the image processing apparatus may be formed as a plurality of apparatuses such as a server, a client, and so on communicate with one another in a collaborative manner.

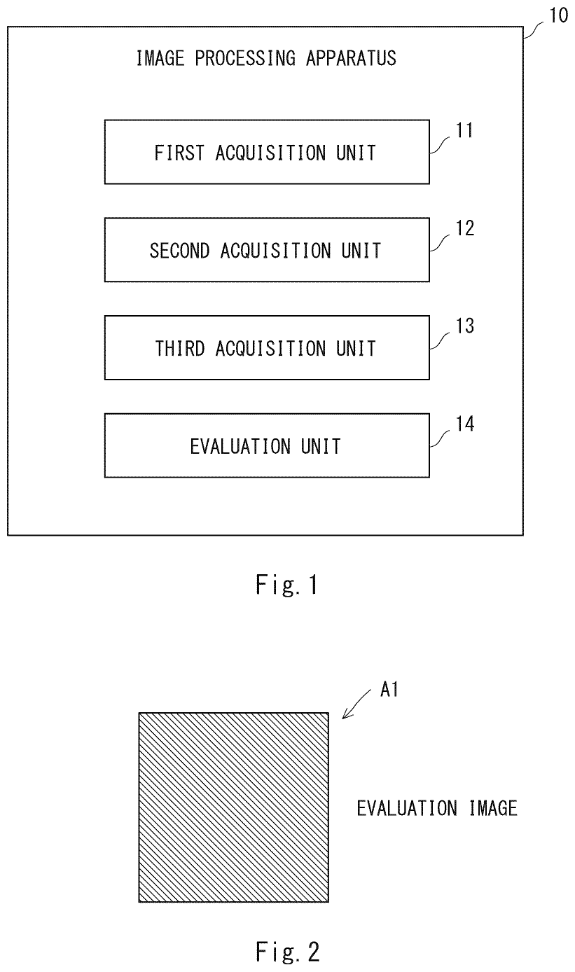

FIG. 1 is a block diagram illustrating an image processing apparatus 10 according to the first embodiment. As shown in FIG. 1, the image processing apparatus 10 includes a first acquisition unit 11, a second acquisition unit 12, and a third acquisition unit 13. The first acquisition unit 11, the second acquisition unit 12, and third acquisition unit 13 include functions as acquisition means. As shown in FIG. 1, the image processing apparatus 10 may include an evaluation unit 14. The evaluation unit 14 includes a function as evaluation means. The following description will be given using an evaluation target mask as an example of the evaluation target.

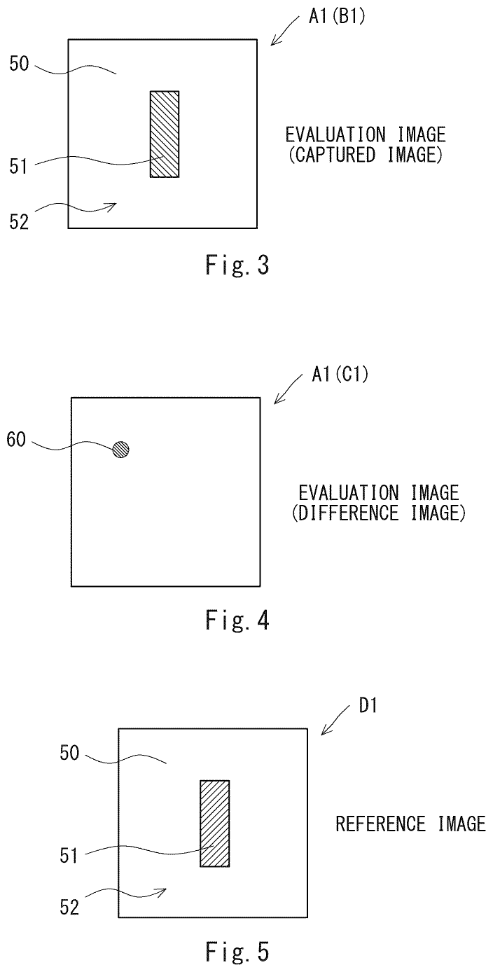

FIGS. 2-4 are diagrams illustrating an evaluation image A1 acquired by the first acquisition unit 11 in the image processing apparatus 10 according to the first embodiment. FIG. 3 shows a captured image B1 as the evaluation image A1 and FIG. 4 shows a difference image C1 as the evaluation image A1. FIG. 5 is a diagram illustrating a reference image D1 that the first acquisition unit 11 uses to acquire the difference image C1 in the image processing apparatus 10 according to the first embodiment. As shown in FIGS. 2-4, the first acquisition unit 11 acquires an evaluation image A1 which is based on a result of imaging a pattern surface 52 on which a pattern 51 of an evaluation target mask 50 is formed.

As shown in FIG. 3, the first acquisition unit 11 may acquire, as the evaluation image A1, a captured image B1 obtained by imaging the pattern surface 52 of the evaluation target mask 50. That is, the evaluation image A1 may include the captured image B1. Further, as shown in FIG. 4, the first acquisition unit 11 may acquire the difference image C1 as the evaluation image A1. That is, the evaluation image A1 may include the difference image C1. The difference image C1 may include a defective image 60. The difference image C1 is an image which is based on comparison between the captured image B1 and the reference image D1 (see FIG. 5) corresponding to the captured image B1, and is, as an example, an image indicating the difference between the captured image B1 and the reference image D1 corresponding to the captured image B1. The reference image D1 may be a non-defective image which shows an image in a case where there is no abnormality in an area of the evaluation target mask 50 shown in the captured image B1 or a case where there is no critical abnormality therein. Alternatively, the reference image D1 may be a comparison image which shows an area whose structure is equivalent to that of the area of the evaluation target mask 50 shown in the captured image B1. The difference image C1 may include, as pixel information, a difference in the luminance between pixels whose relative positions are the same among the pixels of the captured image B1 and the pixels of the reference image D1. The difference image C1 may include, as pixel information, a ratio of the luminance of pixels whose relative positions are the same among the pixels of the captured image B1 and the pixels of the reference image D1. Hereinafter, it is assumed that the difference image C1 is an image indicating the difference between the captured image B1 and the reference image D1 corresponding to the captured image B1, and pixel information of the difference image C1 is simply called luminance.

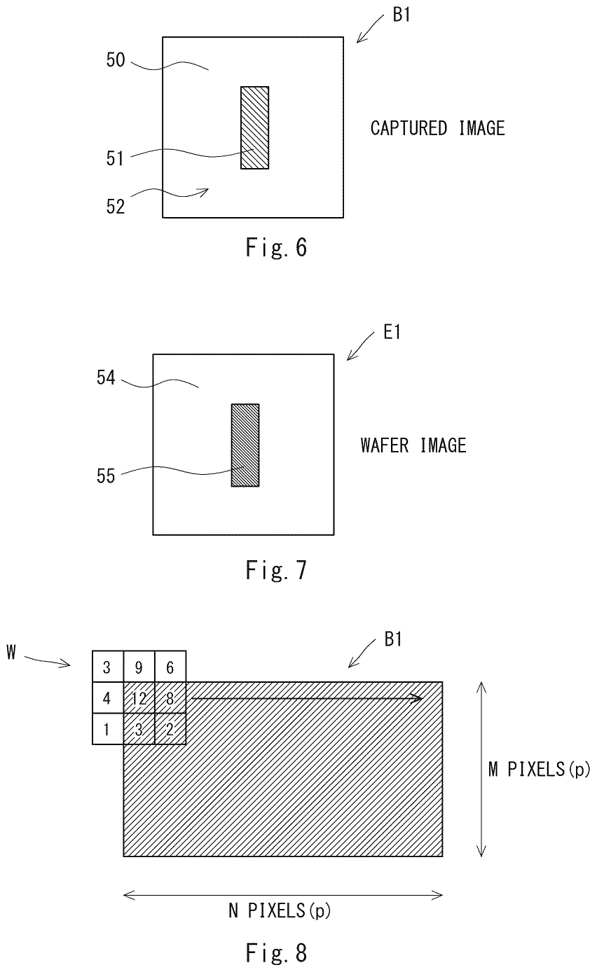

FIG. 6 is a diagram illustrating the captured image B1 that the second acquisition unit 12 uses to acquire conversion parameters in the image processing apparatus 10 according to the first embodiment. FIG. 7 is a diagram illustrating a wafer image E1 that the second acquisition unit 12 uses to acquire conversion parameters in the image processing apparatus 10 according to the first embodiment. The wafer image E1 is an example of a transfer image.

As shown in FIGS. 6 and 7, the second acquisition unit 12 acquires conversion parameters which are based on a relation between the captured image B1 of the pattern surface 52 of the evaluation target mask 50 and the wafer image E1. Here, as described above, the captured image B1 is an image obtained by imaging the pattern surface 52 on which the pattern 51 of the evaluation target mask 50 is formed. The wafer image E1 is an image when the pattern 51 of the evaluation target mask 50 is transferred to the wafer 54 in an exposure apparatus. The wafer image E1 includes an image of a pattern 55 obtained by transferring the pattern 51 of the evaluation target mask 50 to the wafer 54.

The conversion parameters may include first to fourth parameters that will be described below. Further, the conversion parameters may include a fifth parameter. The fifth parameter includes a parameter other than the first to fourth parameters which is based on the relation between the captured image B1 and the wafer image E1. For example, the fifth parameter may include other parameters that will be described later. Note that the conversion parameters may include correction conversion parameters obtained by correcting conversion parameters, as will be described later. The correction conversion parameters are also based on the relation between the captured image B1 and the wafer image E1.

In the following, the conversion parameters acquired by the second acquisition unit 12 will be described separately in <First Parameter: Lithography Conditions>, <Second Parameter: Machine Learning Model>, <Third Parameter: Kernel>, and <Fourth Parameter: Functions of Fourier Transform and Inverse Fourier Transform>

### <First Parameter: Lithography Conditions>

The second acquisition unit 12 may acquire lithography conditions including optical conditions and resist conditions of the exposure apparatus. Then the second acquisition unit 12 may determine a conversion parameter (first parameter) based on the acquired lithography conditions. For example, in the exposure apparatus, the magnification in one direction (e.g., vertical direction) of the mask may be different from the magnification in another direction (e.g., lateral direction) perpendicular to one direction so as to correspond to high NA. In this case, as an example of the optical conditions, the magnification in the other direction with respect to one direction is M-fold. In this case, the second acquisition unit 12 acquires, as a conversion parameter, a first parameter in which the magnification in the other direction with respect to one direction is M-fold.

Note that the optical conditions may include not only the magnification in the other direction with respect to one direction but also a luminance distribution, a contrast distribution or the like of illumination light. Further, the resist conditions may include a width between the patterns 51 formed by resist, and so on.

### <Second Parameter: Machine Learning Model>

The second acquisition unit 12 may train and determine a conversion parameter (second parameter) by machine learning which uses the captured image B1 and the wafer image E1 as a training data set. For example, the second acquisition unit 12 may include a machine learning model. The second acquisition unit 12 causes the machine learning model to learn the captured image B1 and the wafer image E1 as a training data set. Accordingly, the second acquisition unit 12 may acquire the trained machine learning model as the second parameter.

### <Third Parameter: Kernel>

The second acquisition unit may determine, as a conversion parameter (third parameter), a coefficient of a kernel calculated in such a way that a captured image B1 coincides with a wafer image E1 by performing convolution integration in which the captured image B1 is multiplied by the kernel. The second acquisition unit 12 may determine, as a conversion parameter, a kernel that makes the captured image B1 coincide with the wafer image E1 (transfer image) when applied to the captured image B1.

FIG. 8 is a schematic view illustrating a kernel W that the second acquisition unit 12 acquires as a conversion parameter in the image processing apparatus 10 according to the first embodiment. As shown in FIG. 8, the second acquisition unit 12 performs convolution integration in which the captured image B1 is multiplied by the kernel W. The captured image B1 is an image formed of a plurality of pixel rows aligned in a first direction and a plurality of pixel rows aligned in a second direction perpendicular to the first direction. It is assumed, in this example, that the captured image B1 is an image in which M pixels p are aligned in the first direction and N pixels p are aligned in the second direction.

It is assumed that the kernel W having two-dimensional parameters is, for example, a kernel having 3 rows and 3 columns, i.e., 3×3=9 cells. The size of each element (this may be referred to as a coefficient or a cell) of the kernel W may virtually correspond to the size of the pixel p of the captured image B1.

The second acquisition unit 12 performs processing for applying the kernel W to the captured image B1. For example, the second acquisition unit 12 performs convolution processing disclosed in Non-Patent Literature 1. Specifically, in the pixel p corresponding to the center of the kernel W, convolution processing is performed between surrounding 3×3 pixel values (e.g., luminance) and each cell of the kernel W to filter each pixel in the captured image B1. For example, each cell of the kernel W is expressed by (i, j) using local coordinate axes including x and y axes. When a local operator for performing image filtering in neighboring 3× 3 pixels of each pixel p is denoted by J (p), J (p) can be defined as shown in the following Expression (1) as convolution between the luminance value I(x+i, y+j), which is around the pixel p=(x, y) on the captured image B1, and W′ (p) (convolution is a two-dimensional discrete approximation value).

$$\begin{matrix}[ Expression 1 ] & \\ J ( p ) = I * {W}^{′} ( p ) = \frac{1}{S} {\sum }_{i = - k}^{k} {\sum }_{j = - k}^{k} {w}_{i , j}^{′} \cdot I ( x + i , y + j ) & ( 1 )\end{matrix}$$

Here, W′ (p) is a kernel obtained by inverting the original kernel W (p) with respect to both x and y axes of the local coordinate axes. Further, w′_{i, j} is a weighting coefficient at each position (i, j) of the inverted kernel W′ (p), and S>0 is a coefficient for normalization and scaling. When i and j extend beyond the boundary range of the captured image B1, padding processing may be performed first and a pixel value I(x+i, y+j) obtained by adding values to an area around the above position may be used. In this manner, the second acquisition unit 12 performs convolution processing on each pixel of the captured image B1 to output pixel values after processing. The second acquisition unit 12 can sweep the whole captured image B1 by the kernel W by sequentially changing pixels of the captured image B1 where the central cell of the kernel W is arranged. Accordingly, the second acquisition unit 12 acquires a corrected captured image to which the kernel W is applied for the whole captured image B1.

Just like the captured image B1, the corrected captured image is an image in which M pixels are aligned in the first direction and N pixels are aligned in the second direction. The luminance I'_{m, n} in each pixel (p′_{m, n}) of the corrected captured image is changed from the luminance I_{m, n} of each pixel (p_{m, n}) of the captured image B1 by the application of the kernel W.

The second acquisition unit 12 acquires, as a third parameter, a kernel W in which the value of each cell (coefficient) is adjusted in such a way that the corrected captured image coincides with the wafer image E1. For example, the second acquisition unit 12 may specify a coefficient in which a difference between the luminance of each pixel of the corrected captured image when the value of each cell (coefficient) of the kernel W is changed and applied and the luminance of each pixel of the wafer image E1 becomes minimum and determine the kernel W based on this coefficient.

### <Fourth Parameter: Functions of Fourier Transform and Inverse Fourier Transform>

The second acquisition unit 12 may determine a conversion parameter based on a function in an optical model MI for acquiring information of the pattern surface 52 from the captured image B1 and a function in an optical model ML for acquiring the wafer image E1 from information of the pattern surface 52.

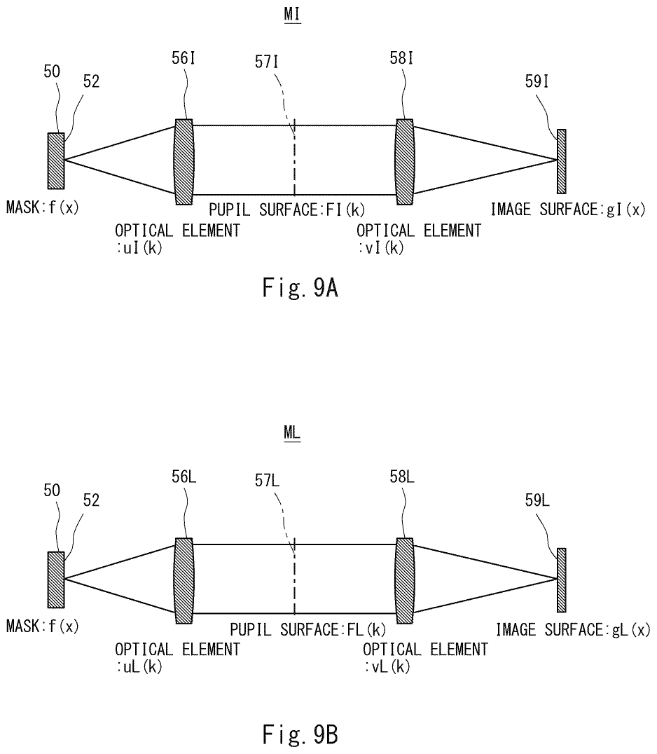

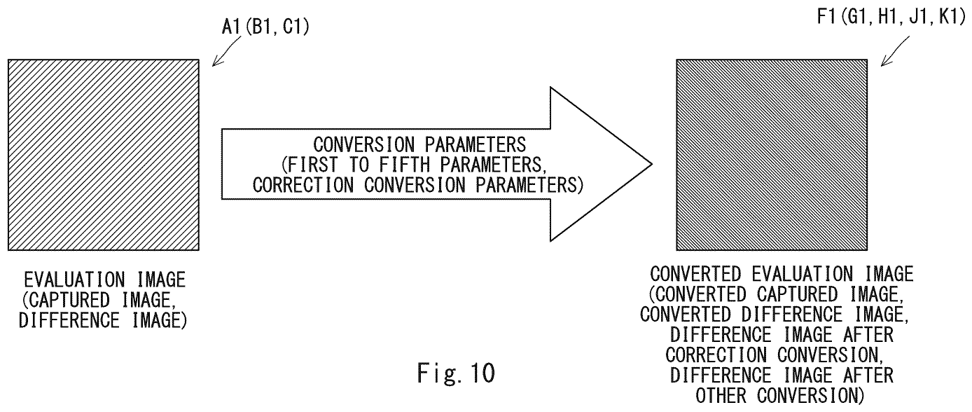

FIGS. 9A and 9B are a diagram illustrating an optical model that the second acquisition unit 12 uses to acquire conversion parameters in the image processing apparatus 10 according to the first embodiment. With reference to FIGS. 9A and 9B, the description will be made using a one-dimensional transmission optical model for the sake of explanation. The actual conversion parameters are acquired by expanding a one dimension to a two dimension. When an optical model that is different from the transmission optical model is used as well, descriptions similar to those shown below can be applied. FIG. 9A shows an optical model MI of an optical apparatus (the optical apparatus may be an evaluation apparatus: hereinafter this apparatus will be referred to as an inspection apparatus) for acquiring the captured image B1 of the pattern surface 52 of the evaluation target mask 50. FIG. 9B shows an optical model ML of the exposure apparatus for performing a lithography process using the evaluation target mask 50 as a patterning device.

As shown in FIG. 9A, the optical model MI of the inspection apparatus includes an optical element 561 and an optical element 58I disposed between a pattern surface 52 of an evaluation target mask 50 and an image surface 591. Illumination light reflected by the pattern surface 52 is concentrated on the image surface 59I via the optical element 56I and the optical element 58I. A pupil surface 57I is formed between the optical element 561 and the optical element 58I.

In FIG. 9A, a one-dimensional position is denoted by x and an angular distribution is denoted by k. The strength of the image surface 591, the strength of the pupil surface 571, and the strength of the pattern surface 52 are respectively expressed by the following Expressions (2), (3), and (4). Here, i is an imaginary number.

$$gI ( x ) \qquad ( 2 )$$

$$FI ( k ) = vI ( k ) \cdot \int gI ( x ) exp ( - ikx ) dx \qquad ( 3 )$$

$$f ( x ) = \int uI ( k ) \cdot FI ( k ) exp ( ikx ) dx \qquad ( 4 )$$

Here, uI(k) is a function that depends on the optical design of the inspection apparatus for reproducing the change in the strength from the pattern surface 52 to the pupil surface 571 by the optical element 561 of the inspection apparatus. Further, vI(k) is a function that depends on the optical design of the inspection apparatus for reproducing the change in the strength from the pupil surface 57I to the image surface 591 by the optical element 581 of the inspection apparatus.

gI(x) correspond to one-dimensional(x-direction) strength of the captured image B1. Therefore, by performing, based on the optical model MI of the inspection apparatus, Fourier transform shown in Expression (3) on gI(x) indicating the strength of the captured image B1 and performing inverse Fourier transform shown in Expression (4) on the obtained FI(k), the strength of the pattern surface 52 of the evaluation target mask 50 (this may correspond to a physically uneven shape) can be calculated from the captured image B1.

As shown in FIG. 9B, the optical model ML of the exposure apparatus includes an optical element 56L and an optical element 58L disposed between a pattern surface 52 of an evaluation target mask 50 (as an application, a mask as a patterning device) and an image surface 59L. Illumination light reflected by the pattern surface 52 is concentrated on the image surface 59L via the optical element 56L and the optical element 58L. A pupil surface 57L is formed between the optical element 56L and the optical element 58L.

In FIG. 9B, a one-dimensional position is denoted by x and an angular distribution is denoted by k. When the strength of the pattern surface 52 is denoted by the above f(x), the strength of the pupil surface 57L and the strength of the image surface 59L are respectively expressed by the following Expressions (5) and (6). Here, the strength gL(x) of the image surface 59L corresponds to one-dimensional (x-direction) strength of the wafer image E1.

$$FL ( x ) = uL ( k ) \cdot \int f ( x ) exp ( - ikx ) dx \qquad ( 5 )$$

$$gL ( x ) = \int vL ( k ) \cdot FL ( k ) exp ( ikx ) dx \qquad ( 6 )$$

Here, uL(k) is a function that depends on the optical design of the exposure apparatus for reproducing the change in the strength from the pattern surface 52 to the pupil surface 57L by the optical element 56L of the exposure apparatus. Further, vL(k) is a function that depends on the optical design of the exposure apparatus for reproducing the change in the strength from the pupil surface 57L to the image surface 59L by the optical element 58L of the exposure apparatus.

f(x) is acquired based on the aforementioned Expression (4). Therefore, the strength of the wafer image E1 can be calculated from the strength f(x) of the pattern surface 52 of the evaluation target mask 50 by performing Fourier transform shown in Expression (5) for f(x) based on the optical model ML of the exposure apparatus and performing inverse Fourier transform shown in Expression (6) on the obtained FL(k).

To sum up, by further performing the Fourier transform shown in Expression (5) and the inverse Fourier transform shown in Expression (6) which are based on the optical model ML of the exposure apparatus on the strength of the pattern surface 52 of the evaluation target mask 50 obtained by performing the Fourier transform shown in Expression (3) and the inverse Fourier transform shown in Expression (4) which are based on the optical model MI of the inspection apparatus on gI(x) indicating the strength of the captured image B1, the wafer image E1 can be calculated and acquired from the captured image B1.

The second acquisition unit 12 acquires a fourth parameter for converting the captured image B1 into a wafer image E1 based on the optical model. Specifically, the second acquisition unit 12 determines the fourth parameter based on a function in the optical model MI for acquiring information of the pattern surface 52 from the captured image B1 and a function in the optical model ML for acquiring the wafer image E1 from information of the pattern surface 52. The fourth parameter may be a parameter that is determined based on the above uI(k), vI(k), uL(k), and vL(k), or may be a parameter that includes the above uI(k), vI(k), uL(k), and vL(k) as an internal coefficient.

FIG. 10 is a diagram illustrating a converted evaluation image F1 acquired by the third acquisition unit 13 in the image processing apparatus 10 according to the first embodiment. As shown in FIG. 10, the third acquisition unit 13 acquires the converted evaluation image F1 by applying conversion parameters to an evaluation image A1. The evaluation image A1 includes a captured image B1 and a difference image C1. The first acquisition unit 11 may acquire, as the difference image C1, an image indicating a difference between the captured image B1 and the converted reference image obtained by applying conversion parameters to the reference image D1. Therefore, the evaluation image A1 may include the difference image C1 between the captured image B1 and the converted reference image.

The conversion parameters include the first to fifth parameters and the correction conversion parameters.

The converted evaluation image F1 includes a converted captured image G1 and a converted difference image H1. For example, the third acquisition unit 13 may acquire, as the converted evaluation image F1, a converted captured image G1 obtained by applying conversion parameters to the captured image B1 (e.g., performing convolution integration in which the captured image B1 is multiplied by the kernel W). At this time, the luminance of at least some of the pixels included in the converted captured image G1 is changed from the luminance of the pixels included in the captured image B1 based on the application of the conversion parameters. Further, the third acquisition unit 13 may acquire, as the converted evaluation image F1, a converted difference image H1 obtained by applying conversion parameters to the difference image C1 (e.g., performing convolution integration in which the difference image C1 is multiplied by the kernel W). At this time, the luminance of at least some of the pixels included in the converted difference image H1 is changed from the luminance of pixels included in the difference image C1 based on the application of the conversion parameters. The converted evaluation image F1 may include a difference image after correction conversion J1 and a difference image after other conversion K1 that will be described later.

The evaluation unit 14 evaluates the pattern surface 52 of the evaluation target mask 50 based on the converted evaluation image F1. Specifically, the evaluation unit 14 evaluates the pattern surface 52 of the evaluation target mask 50 based on the converted captured image G1, the converted difference image H1, the difference image after correction conversion J1, and the difference image after other conversion K1. For example, the evaluation unit 14 may determine that there is a defect in the evaluation target mask 50 when a predetermined defective image 60 has been detected in the converted difference image H1 obtained by applying a conversion parameter to the difference image C1 between the captured image B1 and the reference image D1. Here, the evaluation image A1 is the difference image C1, and the converted evaluation image F1 is the converted difference image H1.

Further, the evaluation unit 14 may determine that there is a defect in the evaluation target mask 50 when a predetermined defective image 60 has been detected in the difference image C1 between the converted captured image G1 obtained by applying conversion parameters to the captured image B1 and the reference image D1 (it may be a converted reference image). Here, the evaluation image A1 is the captured image B1, and the converted evaluation image F1 is the converted captured image G1. In this manner, a configuration in which the evaluation unit 14 determines a defect of the evaluation target mask 50 based on the difference image C1 indicating the difference between the converted captured image G1, which is the converted evaluation image F1, and the reference image D1 (it may be a converted reference image) is also included in a configuration in which the evaluation unit 14 evaluates the pattern surface 52 of the evaluation target mask 50 based on the converted evaluation image F1.

The aforementioned predetermined defective image 60 may include a defective image including pixels with luminance outside a predetermined range, a defective image including a predetermined number or more of pixels with luminance outside the predetermined range, and so on.

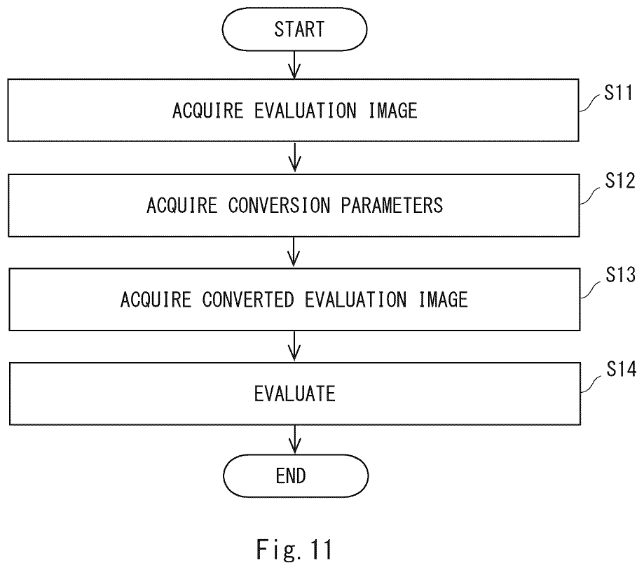

Next, an image processing method according to this embodiment will be described. FIG. 11 is a flowchart illustrating the image processing method according to the first embodiment. As shown in FIG. 11, the image processing method according to this embodiment includes Step S11 of acquiring an evaluation image A1, Step S12 of acquiring conversion parameters, and Step S13 of acquiring a converted evaluation image F1. As shown in FIG. 11, the image processing method according to this embodiment may further include Step S14 of performing evaluation.

In Step S11, the first acquisition unit 11 acquires the evaluation image A1 which is based on a result of imaging the pattern surface 52 on which the pattern 51 of the evaluation target mask 50 is formed. The evaluation image A1 may include a captured image B1 or may include a difference image C1. The first acquisition unit 11 may acquire, as the evaluation image A1, the difference image C1 indicating a difference between the captured image B1 and the reference image D1 corresponding to the captured image B1. Further, the first acquisition unit 11 may acquire, as the difference image C1, an image indicating a difference between the captured image B1 and a converted reference image obtained by applying conversion parameters to the reference image D1 corresponding to the captured image B1.

In Step S12, the second acquisition unit 12 acquires conversion parameters which are based on the relation between the captured image B1 and the wafer image E1. The second acquisition unit 12 may acquire lithography conditions including optical conditions and resist conditions of the exposure apparatus, and determine conversion parameters based on the lithography conditions. Further, the second acquisition unit 12 may train and determine conversion parameters by machine learning that uses the captured image B1 and the wafer image E1 as a training data set. Further, the second acquisition unit 12 may determine, as a conversion parameter, a coefficient of a kernel calculated in such a way that the captured image B1 coincides with the wafer image E1 by performing convolution integration in which the captured image B1 is multiplied by the kernel. Furthermore, the second acquisition unit 12 may determine conversion parameters based on a function in the optical model MI for acquiring information of the pattern surface 52 from the captured image B1 and a function in the optical model ML for acquiring the wafer image E1 from information of the pattern surface 52.

In Step S13, the third acquisition unit 13 applies conversion parameters to the evaluation image A1 to acquire a converted evaluation image F1. For example, the third acquisition unit 13 may acquire, as the converted evaluation image F1, a converted captured image G1 obtained by performing convolution integration in which a kernel is multiplied by the captured image B1. Further, the third acquisition unit 13 may acquire, as the converted evaluation image F1, a converted difference image H1 obtained by applying conversion parameters to the difference image C1.

In Step S14, the evaluation unit 14 evaluates the pattern surface 52 of the evaluation target mask based on the converted evaluation image F1.

Next, effects of this embodiment will be described. The image processing apparatus 10 according to this embodiment acquires conversion parameters which are based on a relation between the captured image B1 of the pattern surface 52 of the evaluation target mask 50 and the wafer image E1 when the pattern surface 52 is transferred to the wafer 54 in an exposure apparatus. Then, the image processing apparatus 10 evaluates the pattern surface 52 of the evaluation target mask 50 based on a converted evaluation image F1 obtained by applying conversion parameters to the evaluation image A1. Accordingly, the image processing apparatus 10 can evaluate a defect candidate found on the pattern surface 52 in consideration of an influence when the pattern surface 52 is transferred to the wafer 54 with a simple configuration.

When a detect or a defect candidate shown on the captured image B1 or the difference image C1 is transferred to the wafer 54 in the exposure apparatus, it is possible that they do not give an adverse effect on a product formed on the wafer 54. The image processing apparatus 10 evaluates whether the defect and the defect candidate shown in the captured image B1 or the difference image C1 may give an adverse effect on the product formed on the wafer 54 by the converted evaluation image F1 converted by conversion parameters in advance. Accordingly, it is possible to evaluate whether a defect or a defect candidate gives an adverse effect even when the evaluation target mask 50 is not actually transferred to the wafer 54 in the exposure apparatus.

The second acquisition unit 12 of the image processing apparatus 10 may determine conversion parameters based on lithography conditions of the exposure apparatus, or may train and determine conversion parameters by machine learning. Further, the second acquisition unit 12 may determine a coefficient of a kernel W as a conversion parameter, or may determine a conversion parameter based on functions of Fourier transform and inverse Fourier transform of the optical model. It is therefore possible to improve the accuracy of evaluating the evaluation target mask 50.

### Second Embodiment

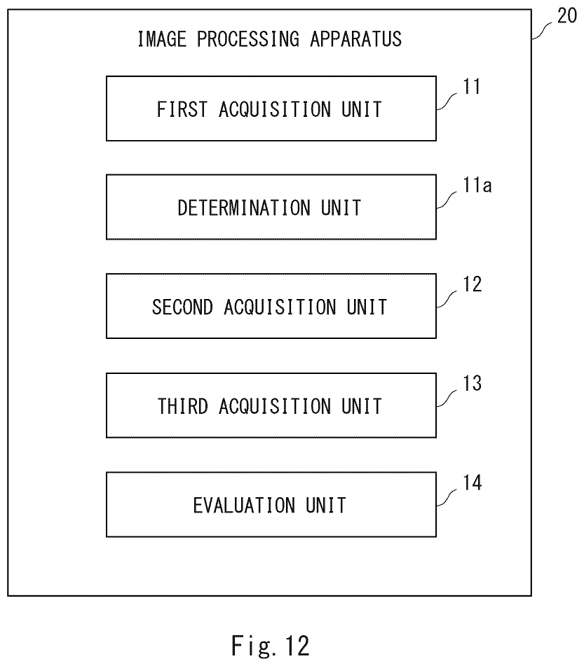

Next, an image processing apparatus according to a second embodiment will be described. The image processing apparatus according to this embodiment includes a determination unit configured to determine predetermined conditions and classification of defective images 60. FIG. 12 is a block diagram illustrating an image processing apparatus 20 according to the second embodiment. As shown in FIG. 12, the image processing apparatus 20 is different from the above-described image processing apparatus 10 in that the image processing apparatus 20 further includes a determination unit 11a. The determination unit 11a includes a function as determination means. An evaluation unit 14 may include the determination unit 11a. The determination unit 11a may include the evaluation unit 14.

The determination unit 11a determines whether an evaluation image A1 satisfies predetermined conditions. The predetermined conditions include, for example, at least one of a condition that a pattern surface 52 in a captured image B1 has a specific shape and a condition that the pattern surface 52 is illuminated in a specific illumination distribution in an exposure apparatus. The pattern surface 52 having a specific shape includes, for example, a case in which the pattern surface 52 has a line shape such as line-and-space, and a hole shape. Illumination in a specific illumination distribution includes, for example, an illumination distribution in a dual-polarized light source. When a pattern 51 of the line and space is exposed, illumination from a dual-polarized light source such as a dipole may be used in order to increase the contrast. In this embodiment, when the determination unit 11a determines that the evaluation image A1 satisfies the predetermined conditions, a second acquisition unit 12 acquires conversion parameters and a third acquisition unit 13 acquires a converted evaluation image F1. Note that the determination unit 11a may determine whether an evaluation target mask 50 satisfies predetermined conditions. When the determination unit 11a determines that the evaluation target mask 50 satisfies the predetermined conditions, the second acquisition unit 12 may acquire conversion parameters and the third acquisition unit 13 may acquire the converted evaluation image F1.

Further, the determination unit 11a may determine whether a difference image C1 satisfies predetermined conditions. The predetermined conditions may include a condition related to at least one of the size, the luminance, a change in the luminance, and the shape of the defective image 60 in the difference image C1. When the determination unit 11a has determined that the difference image C1 satisfies predetermined conditions, the second acquisition unit 12 acquires conversion parameters, and the third acquisition unit 13 acquires a converted difference image H1 as the converted evaluation image F1. The evaluation unit 14 evaluates the pattern surface 52 of the evaluation target mask 50 based on the converted difference image H1.

Accordingly, the image processing apparatus 20 operates the second acquisition unit 12, the third acquisition unit 13, and the evaluation unit 14 when the evaluation image A1 such as the captured image B1 and the difference image C1 satisfies predetermined conditions. When the predetermined conditions are not satisfied, the image processing apparatus 20 does not need to operate the second acquisition unit 12, the third acquisition unit 13, and the evaluation unit 14, whereby it is possible to reduce the cost.

Depending on the size, the luminance, a change in the luminance, and the shape of the defective image 60 in the difference image C1, it may be preferable to apply conversion parameters using the evaluation image F1 as the difference image C1 and perform evaluation based on the converted difference image H1. Accordingly, by setting the conditions such as the size, the luminance, a change in the luminance, and the shape of the defective image 60, it is possible to improve the accuracy of evaluating the evaluation target mask 50.

Further, the determination unit 11a may determine classification of a defective image 60 shown in the difference image C1. For example, the determination unit 11a may classify a change in the luminance in the area of the defective image 60. Specifically, the determination unit 11a may classify defective images 60 into defective images 60 whose changes in the luminance are gentle and defective images 60 whose changes in the luminance are steep. Further, the determination unit 11a may classify the size, the luminance, and the shape of the defective images 60. The determination unit 11a may classify the defective images 60 whose changes in the luminance are gentle and the defective images 60 whose changes in the luminance are steep depending on a threshold in a rate of change in the luminance.

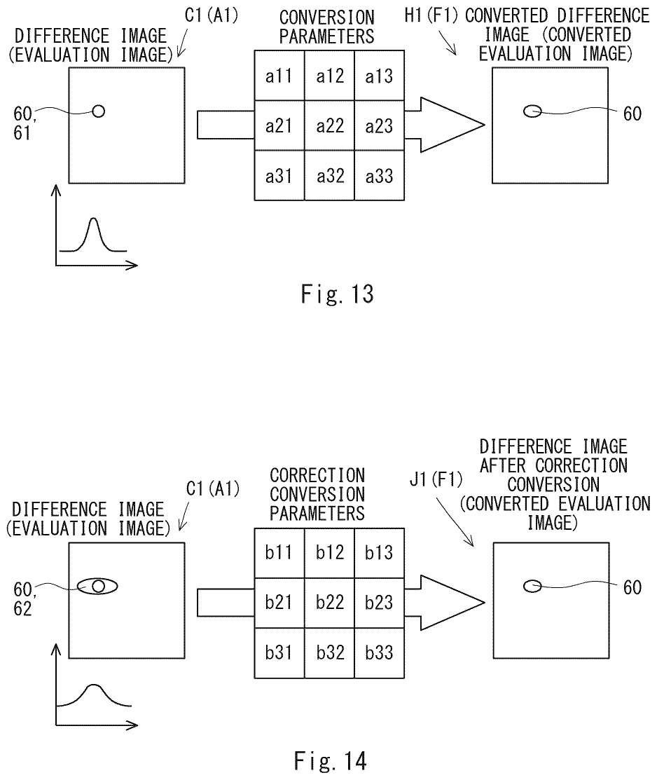

FIGS. 13 and 14 are diagrams illustrating conversion parameters acquired by the second acquisition unit 12 and the converted evaluation image F1 acquired by the third acquisition unit 13 in the image processing apparatus 20 according to the second embodiment. As shown in FIGS. 13 and 14, the second acquisition unit 12 acquires conversion parameters applied to the difference image C1 in accordance with classification of the defective image 60 determined by the determination unit 11a. For example, as shown in FIG. 13, in a case of a classification 61 where a change in luminance in an area of a defective image 60 is steep, the second acquisition unit 12 acquires predetermined conversion parameters which are based on a relation between the captured image B1 and the wafer image E1. The third acquisition unit 13 then applies conversion parameters to the difference image C1 to acquire the converted difference image H1.

On the other hand, as shown in FIG. 14, in a case of a classification 62 in which a change in luminance in an area of a defective image 60 is gentle, the second acquisition unit 12 acquires correction conversion parameters obtained by correcting conversion parameters as conversion parameters. Then, the third acquisition unit 13 applies the correction conversion parameters to the difference image C1 as conversion parameters. Accordingly, the third acquisition unit 13 acquires a difference image after correction conversion J1 as the converted evaluation image F1. The difference image after correction conversion J1 is an image obtained by applying the correction conversion parameters to the difference image C1.

For example, the second acquisition unit 12 may acquire the correction conversion parameters by assigning components of a moving averaging filter and/or a sharpening filter in accordance with the classification of the defective image 60 to conversion parameters. The second acquisition unit 12 may acquire the correction conversion parameters by assigning components of a filter for other purpose in accordance with the classification of the defective image 60 to the conversion parameters. It is possible that a defect that is detected as a defective image 60 of the classification 62 in which the change in the luminance is gentle in the difference image C1 may not be easily detected in the wafer image E1 obtained as a result of transfer in an exposure apparatus. Then, it is possible that the influence of the defective image of the classification 62 may not be appropriately determined. In order to solve this problem, in the case of the defective image 60 of the classification 62 in which the change in the luminance is gentle, correction conversion parameters obtained by further assigning components of the sharpening filter to the conversion parameters are used. As stated above, the second acquisition unit 12 may acquire conversion parameters in accordance with the classification of the defective images 60. Accordingly, it is possible to evaluate the pattern surface 52 of the evaluation target mask 50 in a state in which the influence of an area near the defective image 60 is eliminated.

Note that the determination unit 11a may classify defective images 60 based on the size of the defective image 60, the shape of the defective image 60, the luminance of the defective image 60, the material of the evaluation target mask 50, the material of the wafer 54, or the like, not only based on the change in the luminance in the area of the defective image 60. Further, while conversion parameters are applied in the classification 61 in which the change in the luminance in the area of the defective image 60 is steep and correction conversion parameters are applied in the classification 62 in which the change in the luminance in the area of the defective image 60 is gentle in the above description, this relation may be reversed. In addition, the distinction of the classification is only one example. Therefore, when the defective image 60 in the difference image C1 is a defect (defective image) of first classification, the third acquisition unit 13 may acquire the converted difference image H1 obtained by applying conversion parameters to the difference image C1. On the other hand, when the defective image 60 in the difference image C1 is a defect (defective image) of the second classification, the third acquisition unit 13 may acquire a difference image after correction conversion J1 obtained by applying correction conversion parameters to the difference image C1.

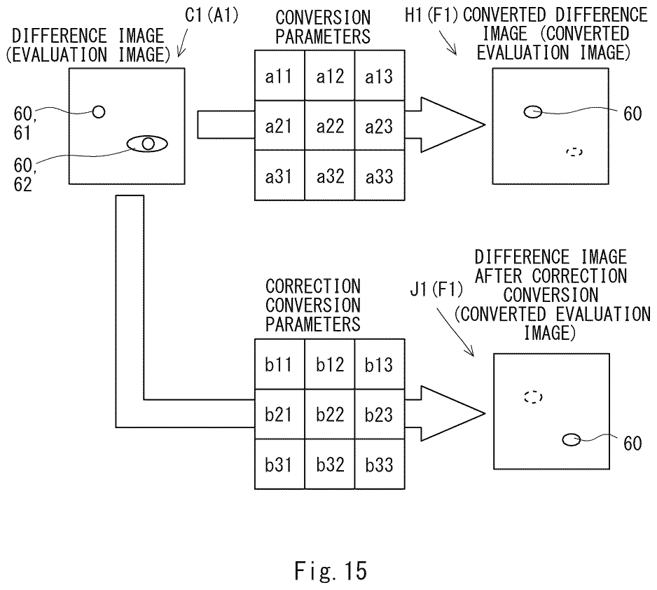

FIG. 15 is a diagram illustrating the conversion parameters acquired by the second acquisition unit 12 and the converted evaluation image F1 acquired by the third acquisition unit 13 in the image processing apparatus 20 according to the second embodiment. As shown in FIG. 15, the third acquisition unit 13 may acquire a converted difference image H1 by applying conversion parameters to the difference image C1. Further, the third acquisition unit 13 may acquire a difference image after correction conversion J1 by applying correction conversion parameters to the difference image C1.

As described above, the image processing apparatus 20 may acquire two evaluation images F1 without determining a defective image 60 by the determination unit 11a. The evaluation unit 14 may determine a defective image 60 detected in the converted difference image H1 to which conversion parameters are applied as a defective image 60 of the classification 61. Further, the evaluation unit 14 may determine a defective image 60 detected in the difference image after correction conversion J1 to which correction conversion parameters are applied as a defective image 60 of the classification 62. As described above, the evaluation unit 14 may include the determination unit 11a. Therefore, the determination unit 11a may determine that the defective image 60 shown in the converted difference image H1 as a defect in a specific classification. Further, the determination unit 11a may determine that the defective image 60 shown in the converted difference image H1 as a defect of the classification 61 and determine that the defective image 60 shown in the difference image after correction conversion J1 as a defect of the classification 62.

By using conversion parameters in accordance with each of the classification 61 and classification 62 of the defective images 60, these defective images 60 may become more noticeable. That is, by applying conversion parameters, it is possible to characteristically extract defective images 60 in a specific specification. Accordingly, by changing conversion parameters, a specific defective image 60 can be selectively detected. Further, an image processing method performed by the image processing apparatus 20 in FIG. 15 can eliminate the need for preliminary classification of the defective images 60 by the determination unit 11a.

The second acquisition unit 12 may acquire other parameters different from the conversion parameters as conversion parameters. The third acquisition unit 13 may acquire, as a converted evaluation image F1, a difference image after other conversion K1 obtained by applying other parameters to the difference image C1. Further, the third acquisition unit 13 may acquire a converted difference image H1 by applying conversion parameters to the difference image C1 and then acquire a correction conversion difference image J1 by applying correction conversion parameters to the converted difference image H1. In this case, the other parameters may be the ones obtained by operating conversion parameters and correction conversion parameters. The other parameters may be the same as the correction conversion parameters, and the correction conversion difference image J1 may be the same as the difference image after other conversion K1. The determination unit 11a may determine that the defective image 60 shown in the converted difference image H1 is a defect of the first classification and determine that the defective image shown in the difference image after other conversion K1 is a defect of second classification.

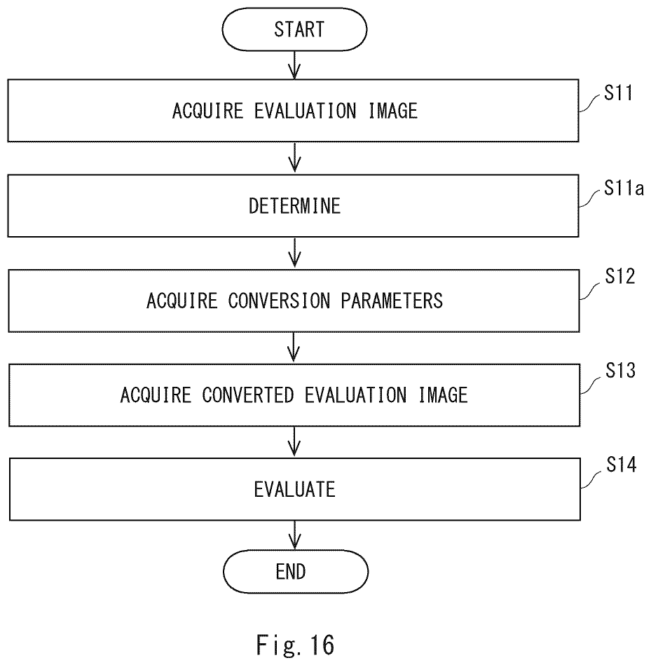

FIG. 16 is a flowchart illustrating the image processing method according to the second embodiment. As shown in FIG. 16, the image processing method according to this embodiment is different from the aforementioned image processing method in that the image processing method according to this embodiment includes Step S11a. In Step S11a, the determination unit 11a determines whether an evaluation image A1 satisfies predetermined conditions. The determination unit 11a may determine whether a difference image C1 satisfies predetermined conditions. Further, the determination unit 11a may determine classification of the defective image 60 shown in the difference image C1.

When it is determined by the determination unit 11a that the evaluation image A1 or the difference image C1 satisfies predetermined conditions, the second acquisition unit 12 may acquire conversion parameters in Step S12. Further, the second acquisition unit 12 acquires, for the defective image 60 shown in the difference image C1, conversion parameters or correction conversion parameters in accordance with the classification determined by the determination unit 11a.

According to this embodiment, the image processing apparatus 20 includes the determination unit 11a that determines classification of the defective image 60 in the difference image C1. Therefore, the image processing apparatus 20 can apply conversion parameters in accordance with the classification of the defective image 60 to the difference image C1. It is therefore possible to improve the accuracy of evaluation. Further, since the image processing apparatus 20 includes the determination unit 11a that determines predetermined conditions, the evaluation image A1 can be determined before conversion parameters are applied to the evaluation image A1. It is therefore possible to determine whether or not to acquire the converted evaluation image F1. It is therefore possible to reduce the processing cost. As described above, the determination unit 11a may determine the classification of the defective image 60 based on the defective image 60 specified based on the converted evaluation image F1 obtained by applying specific conversion parameters to the evaluation image A1. In this case, Step S11a may be provided at a stage later than Step S13.

### Third Embodiment

Next, an optical apparatus according to a third embodiment will be described. The optical apparatus according to this embodiment includes an image processing apparatus. The optical apparatus may include, for example, an inspection apparatus for inspecting an evaluation target mask 50, and an image processing apparatus. Further, the optical apparatus may include a review apparatus and an image processing apparatus. Note that the image processing apparatus may be a part of the inspection apparatus and a part of the review apparatus, and the optical apparatus may be each of the inspection apparatus and the review apparatus themselves. In the following, as one example of the optical apparatus, an inspection apparatus including an image processing apparatus will be described.

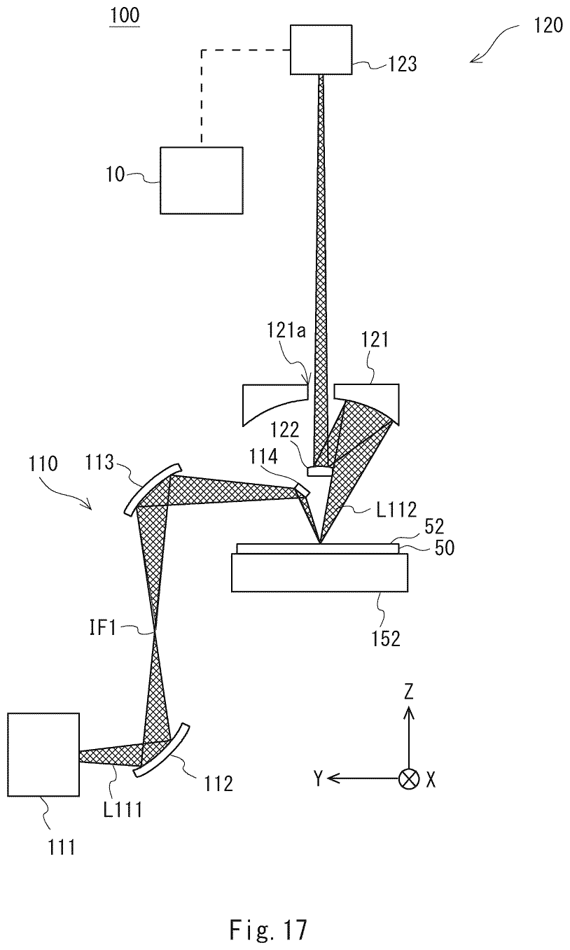

FIG. 17 is a configuration diagram illustrating an inspection apparatus 100 as an optical apparatus according to the third embodiment. The inspection apparatus 100 includes an illumination optical system 110, an imaging optical system 120, and an image processing apparatus 10. Note that the image processing apparatus 10 may be an image processing apparatus 20. The illumination optical system 110 illuminates an evaluation target mask 50 using illumination light L111. The illumination optical system 110 includes, for example, a light source 111, an elliptic mirror 112, an elliptic mirror 113, and a drop-in mirror 114.

The imaging optical system 120 captures a captured image B1 of the evaluation target mask 50 illuminated by the illumination light L111. The imaging optical system 120 includes, for example, a concave mirror 121 with a hole formed therein, a convex mirror 122, and a detector 123. The concave mirror 121 with the hole formed therein and the convex mirror 122 form a Schwarzschild magnification optical system. Note that the illumination optical system 110 and the imaging optical system 120 may further include optical members other than those described above, and do not necessarily have to include all of the above-described optical members.

Here, for the sake of explanation of the inspection apparatus 100, an XYZ-orthogonal coordinate system is introduced. For example, a plane parallel to a stage surface of a stage 152 on which the evaluation target mask 50 is disposed is defined as an XY-plane, and a direction perpendicular to the stage surface is defined as a Z-axis direction. The +Z-axis direction is referred to as upward and the −Z-axis direction is referred to as downward for the sake of convenience. Note that the terms upward and downward are used only for the sake of explanation of the inspection apparatus 100, and they do not indicate directions in which the inspection apparatus 100 is actually disposed.

The light source 111 generates illumination light L111. The illumination light L111 contains, for example, EUV light of 13.5 nm, which is equal to an exposure wavelength of a EUV mask, i.e., the evaluation target mask 50. The illumination light L111 generated by the light source 111 is reflected by the elliptic mirror 112. The illumination light L111 reflected by the elliptic mirror 112 travels while being narrowed, and is concentrated at a concentration point IF1. The concentration point IF1 is positioned at a position conjugate with a pattern surface 52 of the evaluation target mask 50.

After passing through the concentration point IF1, the illumination light L111 travels while being expanded, and is incident on a reflecting mirror such as the elliptic mirror 113. The illumination light L111 incident on the elliptic mirror 113 is reflected by the elliptic mirror 113, travels while being narrowed, and is incident on the drop-in mirror 114. That is, the elliptic mirror 113 makes the illumination light L111 incident on the drop-in mirror 114 as converging light. The drop-in mirror 114 is disposed above the evaluation target mask 50. The illumination light L111 incident on and reflected by the drop-in mirror 114 is incident on the evaluation target mask 50. That is, the drop-in mirror 114 makes the illumination light L111 incident on the evaluation target mask 50.

The elliptic mirror 113 concentrates the illumination light L111 on the evaluation target mask 50. The illumination optical system 110 is disposed so that when the illumination light L111 illuminates the evaluation target mask 50, an image of the light source 111 is formed on the pattern surface 52 of the evaluation target mask 50. Therefore, the illumination optical system 110 provides critical illumination. As described above, the illumination optical system 110 illuminates the evaluation target mask 50 by using the critical illumination by the illumination light L111 generated by the light source 111.

The evaluation target mask 50 is disposed on the stage 152. The illumination light L111 is incident on the evaluation target mask 50 in a direction inclined from the Z-axis direction. That is, the illumination light L111 is obliquely incident on the evaluation target mask 50 as oblique incident illumination. The illumination light L111 may illuminate the evaluation target mask 50 as the oblique incident illumination.

The stage 152 is an XYZ-driven stage. It is possible to illuminate a desired area on the evaluation target mask 50 by moving the stage 152 in the X-axis and Y-axis directions. Further, it is possible to adjust the focus by moving the stage 152 in the Z-axis direction. Further, the stage 152 may be rotated around the X-axis, Y-axis and Z-axis. Note that instead of moving and rotating the stage 152 in the X-axis, the Y-axis, and Z-axis directions, the illumination optical system 110 and the imaging optical system 120 may be moved and rotated.

The illumination light L111 emitted from the light source 111 illuminates a captured area on the evaluation target mask 50. Reflected light L112, i.e., light that has been incident on the evaluation target mask 50 in a direction inclined from the Z-axis direction and reflected by the evaluation target mask 50, is incident on the concave mirror 121 with the hole formed therein. A hole 121a is formed at the center of the concave mirror 121.

The reflected light L112 reflected by the concave mirror 121 with the hole formed therein is incident on the convex mirror 122. The convex mirror 122 reflects the reflected light L112 incident from the concave mirror 121 with the hole formed therein toward the hole 121a of the concave mirror 121. The reflected light L112 passing through the hole 121a is detected by the detector 123. The detector 123 may be a detector 123 including a Time Delay Integration (TDI) sensor.

The detector 123 acquires image data of the evaluation target mask 50. The detector 123 includes a plurality of photographing elements arranged linearly in one direction. Linear image data taken by the plurality of linearly-arranged photographing elements is referred to as one-dimensional image data or one frame. The detector 123 acquires a plurality of such one-dimensional image data by performing scanning in a direction perpendicular to the one direction. The photographing elements are, for example, a Charge Coupled Device(s) (CCDs). Note that the photographing elements are not limited to the CCD(s).

In this way, the imaging optical system 120 concentrates the reflected light L112 coming from the evaluation target mask 50 illuminated by the illumination light L111, and acquires image data of the evaluation target mask 50 by having the detector 123 detect the concentrated reflected light L112. The image data is, for example, two-dimensional image data.

The reflected light L112 contains information about a defective image 60 or the like on the evaluation target mask 50. The normal reflected light of the illumination light L111 that has been incident on the evaluation target mask 50 in the direction inclined from the Z-axis direction is detected by the imaging optical system 120. When there is a defect on the evaluation target mask 50, the defective image 60 is observed as a dark image. Such an observation method is referred to as bright-field observation. The plurality of one-dimensional image data of the evaluation target mask 50 acquired by the detector 123 are output to the image processing apparatus 10 and processed into two-dimensional image data.

The image processing apparatus 10 is connected to the imaging optical system 120 by a signal line or wirelessly. The image processing apparatus 10 receives the image data of the evaluation target mask 50 from the detector 123 in the imaging optical system 120. The image processing apparatus 10 performs image processing on the image data of the evaluation target mask 50 received from the detector 123 as a two-dimensional captured image B1. Specifically, the image processing apparatus 10 converts the captured image B1 into a converted captured image G1 based on conversion parameters.

The evaluation target mask 50 is, for example, an EUV mask sensitive to EUV light. Note that the evaluation target mask 50 is not limited to the EUV mask. The evaluation target mask 50 may be a photomask sensitive to the illumination light L111 having other wavelengths. Further, as described above, the evaluation target mask 50 may be a semiconductor substrate, a semiconductor chip, a semiconductor device, or the like.

While embodiments according to the present disclosure have been described above, the present disclosure includes modifications as appropriate without impairing the objects and advantages thereof, and is not limited by the above-described embodiments. Further, combinations of the configurations of the first to third embodiments and their modified examples are also within the scope of the technical concept of the present disclosure.

A program can be stored and provided to a computer using any type of non-transitory computer readable media. Non-transitory computer readable media include any type of tangible storage media. Examples of non-transitory computer readable media include magnetic storage media (such as flexible disks, magnetic tapes, hard disk drives, etc.), optical magnetic storage media (e.g. magneto-optical disks), CD-ROM (compact disc read only memory), CD-R, CD-R/W, and semiconductor memories (such as mask ROM, PROM (programmable ROM), EPROM (erasable PROM), flash ROM, RAM (random access memory), etc.). The program may be provided to a computer using any type of transitory computer readable media. Examples of transitory computer readable media include electric signals, optical signals, and electromagnetic waves. Transitory computer readable media can provide the program to a computer via a wired communication line (e.g. electric wires, and optical fibers) or a wireless communication line.

The first to third embodiments can be combined as desirable by one of ordinary skill in the art.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. An image processing apparatus, comprising:
a first acquisition unit configured to acquire an evaluation image which is based on a result of imaging a pattern surface on which a pattern of an evaluation target mask is formed;
a second acquisition unit configured to acquire a conversion parameter which is based on a relation between a captured image of the pattern surface and a transfer image when the pattern surface is transferred to a wafer in an exposure apparatus; and
a third acquisition unit configured to acquire a converted evaluation image by applying the conversion parameter to the evaluation image.

2. The image processing apparatus according to claim 1, wherein:
the second acquisition unit acquires a lithography condition including an optical condition and a resist condition of the exposure apparatus, and
the second acquisition unit determines the conversion parameter based on the lithography condition.

3. The image processing apparatus according to claim 1, wherein the second acquisition unit trains and determines the conversion parameter by machine learning which uses the captured image and the transfer image as a training data set.

4. The image processing apparatus according to claim 1, wherein the second acquisition unit determines, as the conversion parameter, a kernel which makes the captured image coincide with the transfer image when the kernel is applied to the captured image.

5. The image processing apparatus according to claim 4, wherein:
the evaluation image includes the captured image, and
the third acquisition unit acquires, as the converted evaluation image, a converted captured image obtained by performing convolution integration in which the captured image is multiplied by the kernel.

6. The image processing apparatus according to claim 1, wherein the second acquisition unit determines the conversion parameter based on a function in an optical model that acquires information of the pattern surface from the captured image and a function in an optical model that acquires the transfer image from the information of the pattern surface.

7. The image processing apparatus according to claim 1, wherein:
the first acquisition unit acquires a difference image indicating a difference between the captured image and a reference image corresponding to the captured image as the evaluation image, and
the third acquisition unit acquires a converted difference image obtained by applying the conversion parameter to the difference image as the converted evaluation image.

8. The image processing apparatus according to claim 7, further comprising a determination unit configured to determine whether the difference image satisfies a predetermined condition, wherein:
when the determination unit determines that the predetermined condition is satisfied, the third acquisition unit acquires the converted difference image as the converted evaluation image.

9. The image processing apparatus according to claim 7, comprising an evaluation unit configured to determine that there is a defect in the evaluation target mask when a predetermined defective image is detected in the converted difference image.

10. The image processing apparatus according to claim 7, further comprising a determination unit configured to determine classification of a defective image shown in the difference image, wherein:
the second acquisition unit acquires, in accordance with the classification determined by the determination unit, a correction conversion parameter obtained by correcting the conversion parameter as the conversion parameter, and
the third acquisition unit acquires, as the converted evaluation image, a difference image after correction conversion obtained by applying the correction conversion parameter to the difference image.

11. The image processing apparatus according to claim 7, further comprising a determination unit configured to determine a defective image shown in the converted difference image as a defect in a specific classification.

12. The image processing apparatus according to claim 11, wherein:
the second acquisition unit acquires a second parameter different from the conversion parameter as a second conversion parameter,
the third acquisition unit acquires a difference image after other conversion obtained by applying the second parameter to the difference image, and
the determination unit determines a defective image shown in the converted difference image as a defect of first classification and determines a defective image shown in the difference image after other conversion as a defect of second classification.

13. The image processing apparatus according to claim 1, further comprising a determination unit configured to determine whether the evaluation target mask satisfies a predetermined condition, wherein:
when the determination unit determines that the predetermined condition is satisfied, the third acquisition unit acquires the converted evaluation image.

14. The image processing apparatus according to claim 13, wherein the predetermined condition includes at least one of a condition that the pattern surface of the evaluation target mask is illuminated in a specific illumination distribution in the exposure apparatus and a condition that the pattern surface has a specific shape.

15. An image processing method comprising:
a step of acquiring an evaluation image which is based on a result of imaging a pattern surface on which a pattern of an evaluation target mask is formed;
a step of acquiring a conversion parameter which is based on a relation between a captured image of the pattern surface and a transfer image when the pattern surface is transferred to a wafer in an exposure apparatus; and
a step of acquiring a converted evaluation image by applying the conversion parameter to the evaluation image.

16. The image processing method according to claim 15, wherein, in the step of acquiring the conversion parameter:
a lithography condition including an optical condition and a resist condition of the exposure apparatus is acquired, and
the conversion parameter is determined based on the lithography condition.

17. The image processing method according to claim 15, wherein:
in the step of acquiring the conversion parameter, the conversion parameter is trained and determined by machine learning which uses the captured image and the transfer image as a training data set.

18. The image processing method according to claim 15, wherein:
in the step of acquiring the conversion parameter, a kernel which makes the captured image coincide with the transfer image when the kernel is applied to the captured image is determined as the conversion parameter.

19. The image processing method according to claim 18, wherein:
the evaluation image includes the captured image, and
in the step of acquiring the converted evaluation image, a converted captured image obtained by performing convolution integration in which the captured image is multiplied by the kernel is acquired as the converted evaluation image.

20. The image processing method according to claim 15, wherein:
in the step of acquiring the conversion parameter, the conversion parameter is determined based on a function in an optical model that acquires information of the pattern surface from the captured image and a function in an optical model that acquires the transfer image from the information of the pattern surface.

21. The image processing method according to claim 15, wherein:
in the step of acquiring the evaluation image, a difference image indicating a difference between the captured image and a reference image corresponding to the captured image is acquired as the evaluation image, and
in the step of acquiring the converted evaluation image, a converted difference image obtained by applying the conversion parameter to the difference image is acquired as the converted evaluation image.

22. The image processing method according to claim 21, further comprising a step of determining whether the difference image satisfies a predetermined condition, wherein:
when it is determined, in the step of determining, that the predetermined condition is satisfied, in the step of acquiring the converted evaluation image, the converted difference image is acquired as the converted evaluation image.

23. The image processing method according to claim 21, comprising a step of determining that there is a defect in the evaluation target mask when a predetermined defective image is detected in the converted difference image.

24. The image processing method according to claim 21, further comprising a step of determining classification of a defective image shown in the difference image, wherein:
in the step of acquiring the conversion parameter, a correction conversion parameter obtained by correcting the conversion parameter is acquired as the conversion parameter in accordance with the determined classification, and
in the step of acquiring the converted evaluation image, a difference image after correction conversion obtained by applying the correction conversion parameter to the difference image is acquired as the converted evaluation image.

25. The image processing method according to claim 21, further comprising a step of determining a defective image shown in the converted difference image as a defect in a specific classification.

26. The image processing method according to claim 25, wherein:
in the step of acquiring the conversion parameter, a second parameter different from the conversion parameter is acquired as the conversion parameter,
in the step of acquiring the converted evaluation image, a difference image after other conversion obtained by applying the second parameter to the difference image is acquired, and
in the step of determining, a defective image shown in the converted difference image is determined as a defect of first classification and a defective image shown in the difference image after other conversion is determined as a defect of second classification.

27. The image processing method according to claim 15, further comprising a step of determining whether the evaluation target mask satisfies a predetermined condition, wherein:
when it is determined, in the step of determining, that the predetermined condition is satisfied, in the step of acquiring the converted evaluation image, the converted evaluation image is acquired.

28. The image processing method according to claim 27, wherein the predetermined condition includes at least one of a condition that the pattern surface of the evaluation target mask is illuminated in a specific illumination distribution in the exposure apparatus and a condition that the pattern surface has a specific shape.
